(19) United States
(12) Patent Application Publication
(10) Pub. No.: US 2025/0357425 A1
(43) Pub. Date: Nov. 20, 2025

(54) SEMICONDUCTOR PACKAGE INCLUDING A SEMICONDUCTOR DIE MATRIX TILE

(71) Applicant: Sandisk Technologies, Inc., Milpitas, CA (US)

(72) Inventors: Weng Khoon Mong, Penang (MY); Choong Keat Loh, Georgetown (MY); Huirong Zhang, Shanghai (CN); Yaqun Zhang, Shanghai (CN); Fumitoshi Ito, Yokohama (JP)

(21) Appl. No.: 18/665,523

(22) Filed: May 15, 2024

(51) Int. Cl. H01L 25/065; H01L 23/00; H01L 23/498

(52) U.S. Cl. CPC H01L 25/0652; H01L 23/49811; H01L 24/24; H01L 2224/24137; H01L 2224/244; H01L 2225/06562

(57) ABSTRACT

A semiconductor package includes a stack of semiconductor die matrix tiles. Each semiconductor die matrix tile in the stack includes two or more unsingulated semiconductor dies that form a single unit. A redistribution layer is provided on each semiconductor die matrix tile and includes a number of traces that electrically couple the two or more unsingulated semiconductor dies. The semiconductor package is mounted on a PCB of a computing component to increase the capacity and performance capabilities of the computing component without occupying additional space on the PCB.

### BACKGROUND

A computing component typically includes a number of semiconductor packages mounted on a printed circuit board (PCB). For example, a solid state drive (SSD) typically includes a number of individual NAND memory packages mounted on the PCB.

Capabilities of the computing component may be increased by adding additional semiconductor packages. For example, in order to increase the capacity of a SSD, additional NAND memory packages are mounted on the PCB. However, when placing multiple NAND memory packages on the PCB, a clearance or spacing requirement dictates a minimum amount of space that is required between each NAND memory package. Thus, the number of NAND memory packages that may be added to the computing component is limited by a desired size of the computing component.

Accordingly, it would be beneficial to increase the capabilities of a computing component without increasing a size of the computing component.

### SUMMARY

The present application describes a semiconductor package that includes a stack of semiconductor dies. In an example, each semiconductor die in the stack of semiconductor dies are NAND memory dies. However, unlike traditional NAND memory dies (or semiconductor dies) that are singulated into single, standalone units, two or more of the semiconductor dies are unsingulated and form semiconductor die matrix tiles.

For example, during a semiconductor die singulation process, a wafer on which the semiconductor dies are fabricated is cut or separated in a manner to form one or more semiconductor die matrix tiles. Each semiconductor die matrix tile includes two or more conjoined semiconductor dies that form a single unit. To create the semiconductor die matrix tile, during the semiconductor die singulation process, a saw street, a die separation line or a scribe lane between two semiconductor dies is skipped or is otherwise left uncut. As a result, a 2×1 semiconductor die matrix tile is formed in which two memory dies are adjacent and connected to one another. In another example, the semiconductor die matrix tile includes four memory dies adjacent and connected to one another. As with the previous example, during the die singulation process, two or more die separation lines or scribe lanes are skipped or are otherwise left uncut to form a 2×2 semiconductor die matrix tile.

A redistribution layer (RDL) is provided on or over each semiconductor die in the semiconductor die matrix tile. The RDL includes traces that electrically couple one or more bond pads or other connection points on one semiconductor die of the semiconductor die matrix tile to one or more bond pads or connection points on the other semiconductor dies of the semiconductor die matrix tile.

Accordingly, examples of the present disclosure describe a semiconductor package that includes a substrate and a stack of semiconductor die matrix tiles electrically coupled to the substrate. In an example, each semiconductor die matrix tile in the stack of semiconductor die matrix tiles includes a first semiconductor die and a second semiconductor die unsingulated from the first semiconductor die such that the first semiconductor die and the second semiconductor die form a single unit. The semiconductor package also includes a redistribution layer. In an example, the redistribution layer includes one or more communication paths that electrically couple the first semiconductor die to the second semiconductor die.

In another example, a semiconductor package is described. The semiconductor package includes a substrate, a first semiconductor die matrix tile comprising a first plurality of conjoined semiconductor dies and a second semiconductor die matrix tile stacked on top of the first semiconductor die matrix tile and comprising a second plurality of conjoined memory dies. In an example, the semiconductor package also includes a first plurality of redistribution layer bond pads provided on the first semiconductor die matrix tile and a second plurality of redistribution layer bond pads provided on the second semiconductor die matrix tile. A bond wire extends between at least a first redistribution layer bond pad of the first plurality of redistribution layer bond pads on the first semiconductor die matrix tile and at least a first redistribution layer bond pad of the second plurality of redistribution layer bond pads on the second semiconductor die matrix tile.

Other examples describe a semiconductor package that includes a substrate and a stack of semiconductor die matrix tiles. In an example, each semiconductor die matrix tile in the stack of semiconductor die matrix tiles includes a first semiconductor die and a second semiconductor die unsingulated from the first semiconductor die such that the first semiconductor die and the second semiconductor die form a single unit. Each semiconductor die matrix tile also includes a trace distribution means provided on the first semiconductor die and the second semiconductor die and a trace means provided within the trace distribution means. In an example, the trace means electrically couples the second semiconductor die to the first semiconductor die. The semiconductor package also includes connection means for electrically coupling each semiconductor die matrix tile in the stack of semiconductor die matrix tiles to the substrate.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a semiconductor die matrix tile having a number of unsingulated semiconductor dies according to an example.

FIG. 1B illustrates a semiconductor die matrix tile having a number of unsingulated semiconductor dies according to another example.

FIG. 1C illustrates a cross-section view of the semiconductor die matrix tile of FIG. 1B according to an example.

FIG. 2 illustrates a semiconductor package having a stack of semiconductor die matrix tiles according to an example.

FIG. 3 illustrates a semiconductor die matrix tile having a number of unsingulated semiconductor dies according to yet another example.

FIG. 4A illustrates a semiconductor package having a stack of semiconductor die matrix tiles according to an example.

FIG. 4B illustrates a cross-section view of the semiconductor package of FIG. 4A according to an example.

FIG. 5 illustrates a redistribution layer for a semiconductor die matrix tile according to an example.

FIG. 6A illustrates a flip chip semiconductor package having a semiconductor die matrix tile according to an example.

FIG. 6B illustrates the semiconductor package of FIG. 6A being electrically coupled to a printed circuit board according to an example.

FIG. 7 illustrates a semiconductor wafer having a number of semiconductor dies forming a semiconductor die matrix tile according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. The following detailed description is therefore not to be taken in a limiting sense, and the scope of the present disclosure is defined by the appended claims and their equivalents.

Computing components typically include a number of semiconductor packages that are surface mounted or are otherwise coupled to a printed circuit board (PCB). Typically, each semiconductor package includes one or more integrated circuits. The number and type of semiconductor packages included with a particular computing component may vary depending on the intended use and/or desired performance capabilities of the computing component. For example, a memory device, such as a solid state drive (SSD), may include a number of individual NAND memory packages that are mounted on a PCB and each NAND memory package includes a stack of NAND memory dies.

However, as each semiconductor package is mounted on the PCB, a clearance or spacing requirement dictates a minimum amount of space that is required between each semiconductor package. Thus, the number of semiconductor packages that may be added to the computing component is limited by a desired size of the computing component. In examples in which the semiconductor package is a NAND memory package, the overall capacity and/or performance capabilities of the semiconductor package is also limited by the desired size of the computing component and/or the number of NAND memory packages that can be placed on the PCB while still conforming to the spacing requirements.

To address the above, the present application describes a semiconductor package having one or more semiconductor die matrix tiles. In an example, each semiconductor die matrix tile includes at least two conjoined or unsingulated semiconductor dies. For example, during a singulation operation of a semiconductor die fabrication process, one or more die separation lines of the semiconductor wafer are skipped. As a result, multiple semiconductor dies remain connected together to form a single unit. In one example, the unsingulated semiconductor dies form a 2×1 semiconductor die matrix tile. In another example, the unsingulated semiconductor dies form a 2×2 semiconductor die matrix tile. Although a 2×1 and a 2×2 matrix tile are specifically mentioned, various die separation lines or scribe lanes on the semiconductor wafer may be skipped to form a semiconductor die matrix tile of any size and/or configuration.

In an example, the semiconductor dies in the semiconductor die matrix tile are accessed individually. For example, each semiconductor die in the semiconductor die matrix tile has one or more bond pads that are used to electrically couple (e.g., using bond wires) each semiconductor die to a substrate of the semiconductor package. In another example, the semiconductor die matrix tile includes a redistribution layer (RDL) that includes one or more traces or other circuitry that electrically couples a first semiconductor die in the semiconductor die matrix tile to a second semiconductor die in the semiconductor die matrix tile. In such an example, the RDL includes or is associated with a RDL bond pad. The RDL bond pad is also electrically coupled to at least one bond pad of at least one semiconductor die in the semiconductor die matrix tile. The RDL bond pad is used to electrically couple the semiconductor die matrix tile to a substrate or printed circuit board (PCB).

In yet another example, the RDL bond pads are coupled to various interconnects, such as, for example, one or more solder balls. In an example, the solder balls electrically couple the semiconductor package to a printed circuit board (PCB).

Accordingly, many technical benefits may be realized including, but not limited to, increasing the capabilities of a semiconductor package while maintaining space requirements and maintaining or reducing a footprint of the semiconductor package. Additional benefits includes reducing an amount of time required for singulation operations since one or more die separation lines or scribe lanes are skipped. As fabrication time decreases, the number of units that are produced in a given time period, when compared with current solutions, increases.

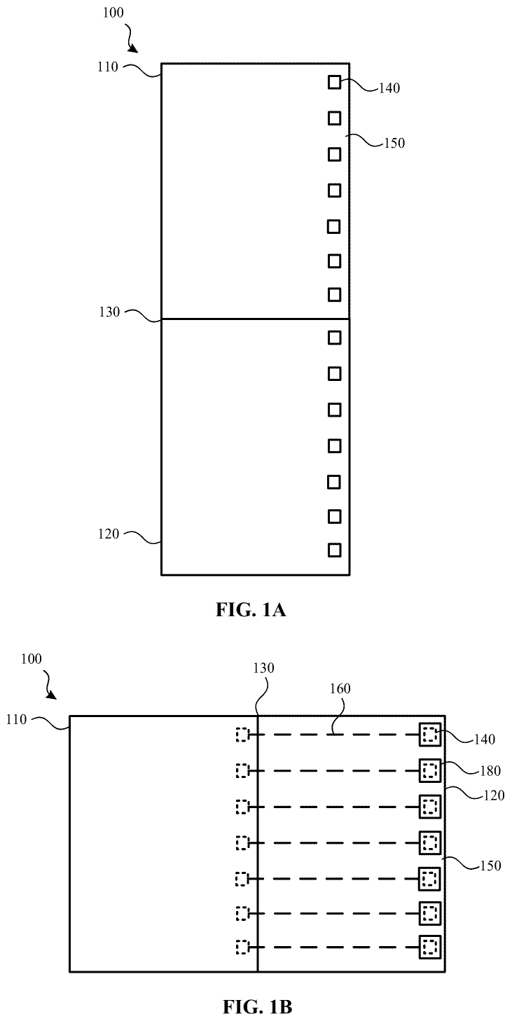

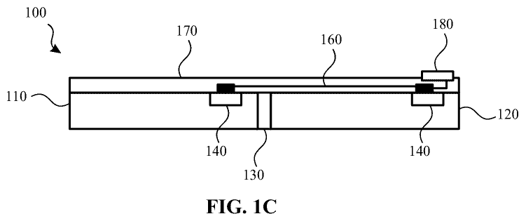

These and other examples will be shown and described in greater detail with respect to FIG. 1A-FIG. 7.

FIG. 1A illustrates a semiconductor die matrix tile 100 having a number of unsingulated semiconductor dies according to an example. For example, the semiconductor die matrix tile 100 includes a first semiconductor die 110 that is conjoined with, or unsingulated from, a second semiconductor die 120. In an example, the first semiconductor die 110 and the second semiconductor die 120 are NAND memory dies. Although NAND memory dies are specifically mentioned, each semiconductor die in the semiconductor die matrix tile 100 may be any type of semiconductor die.

In an example, and as will be described in more detail herein, the first semiconductor die 110 and the second semiconductor die 120 are fabricated on the same semiconductor wafer during the same fabrication process. However, during a singulation operation or process of the semiconductor wafer fabrication process, a scribe lane or die separation line 130 between the first semiconductor die 110 and the second semiconductor die 120 is skipped and remains uncut. As such, the scribe lane or die separation line is visible on a surface of the semiconductor dies.

In the example shown in FIG. 1A, the die separation line 130 that is uncut or skipped during the singulation operation is located between a bottom edge of the first semiconductor die 110 and a top edge of the second semiconductor die 120. As such a 2×1 semiconductor die matrix tile 100 is formed. However, as will be explained in greater detail herein, the uncut die separation line 130 may be provided on any side or edge of a semiconductor die.

In an example, each semiconductor die in the semiconductor die matrix tile 100 includes one or more bond pads 140. The bond pads 140 are positioned proximate an edge 150 of each semiconductor die. As such, one or more bond wires or other connection mechanisms may be used to electrically couple each semiconductor die in the semiconductor die matrix tile 100 to a substrate on which the semiconductor die matrix tile 100 is placed.

FIG. 1B illustrates a semiconductor die matrix tile 100 having a number of unsingulated semiconductor dies according to another example. In this example, the first semiconductor die 110 and the second semiconductor die 120 form a 1×2 semiconductor die matrix tile 100. For example, the die separation line 130 that remains uncut and/or is visible is located on the right side of the first semiconductor die 110 and on the left side of the second semiconductor die 120.

In an example, at least one of the first semiconductor die 110 and the second semiconductor die 120 include bond pads 140 provided proximate to an edge 150. However, in examples in which the first semiconductor die 110 includes bond pads 140 proximate an edge, due to the positioning of the first semiconductor die 110 with respect to the second semiconductor die 120, the bond pads 140 on the first semiconductor die 110 are not easily accessible. As such, one or more traces 160 (e.g., copper or metal traces) or other communication paths are provided between the bond pads (or other connection points) on the second semiconductor die 120 and the first semiconductor die 110. Although the traces 160 are shown in a straight line, the traces 160 may connect any number of bond pads 140 on the first semiconductor die 110 to any number of other bond pads on the first semiconductor die 110 and/or the second semiconductor die 120.

For example, a redistribution layer (RDL) is included on a top surface of the semiconductor die matrix tile 100. The RDL includes the traces 160 that couple bond pads 140 on the first semiconductor die 110 to bond pads 140 on the second semiconductor die 120. In an example, a RDL bond pad 180 is provide on or adjacent the RDL layer and provides a connection point for a bond wire or other connection mechanism.

In another example, the semiconductor wafer is fabricated in a manner such that the bond pads 140 are positioned on opposite sides of each semiconductor die. For example, bond pads 140 are positioned on a first side (e.g., a right side) of the first semiconductor die 110 and bond pads 140 are positioned on a second side (e.g., a left side) of the second semiconductor die 120. As such, bond wires may be used to electrically couple each semiconductor die to corresponding bond pads on the substrate. In another example, a RDL layer and one or more traces 160 may be used to couple the various bond pads 140 such as previously described.

In one example, each semiconductor die in the semiconductor die matrix tile 100 functions as a single unit. In another example, each semiconductor die in the semiconductor die matrix tile 100 functions individually (e.g., is accessed individually).

FIG. 1C illustrates a cross-section view of the semiconductor die matrix tile 100 of FIG. 1B according to an example. As shown in FIG. 1C, a redistribution layer (RDL) 170 is provided over/on a surface of the first semiconductor die 110, the second semiconductor die 120 and the die separation line 130. In an example, the traces 160 that connect the bond pad 140 on the first semiconductor die 110 to the bond pad 140 on the second semiconductor die 120 are contained within the RDL 170. Additionally, the RDL 170 includes a bond pad 180 or other connection point that enables the semiconductor die matrix tile 100 to be communicatively coupled to a substrate, a PCB and/or another semiconductor die matrix tile.

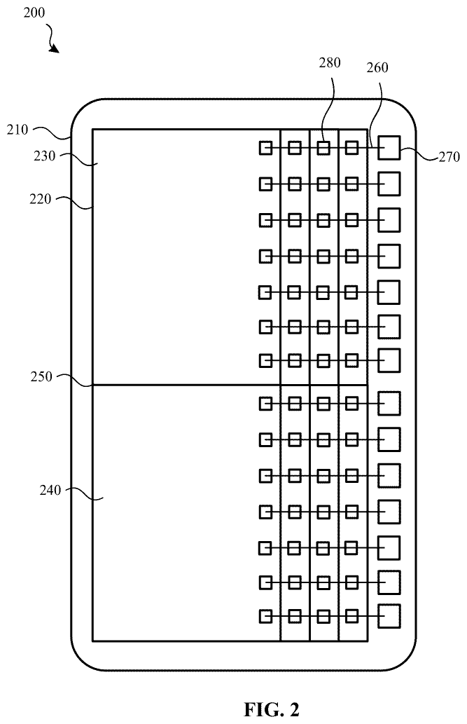

FIG. 2 illustrates a semiconductor package 200 having a stack of semiconductor die matrix tiles 220 according to an example. In an example, each semiconductor die matrix tile in the stack of semiconductor die matrix tiles 220 is similar to the semiconductor die matrix tile 100 shown and described with respect to FIG. 1A. For example, each semiconductor die matrix tile in the stack of semiconductor die matrix tiles 220 includes a first semiconductor die 230 unsingulated or conjoined with a second semiconductor die 240. As with other examples, because the first semiconductor die 230 is unsingulated from the second semiconductor die 240, a die separation line 250 between the first semiconductor die 230 and the second semiconductor die 240 remains visible and/or is uncut.

In an example, the stack of semiconductor die matrix tiles 220 is provided on a substrate 210. Additionally, each semiconductor die matrix tile in the stack of semiconductor die matrix tiles 220 is electrically coupled to the substrate 210. For example bond wires 260 are used to electrically couple a bond pad 270 on a surface of the substrate 210 to corresponding bond pads 280 on each semiconductor die in each semiconductor die matrix tile of the stack of semiconductor die matrix tiles 220.

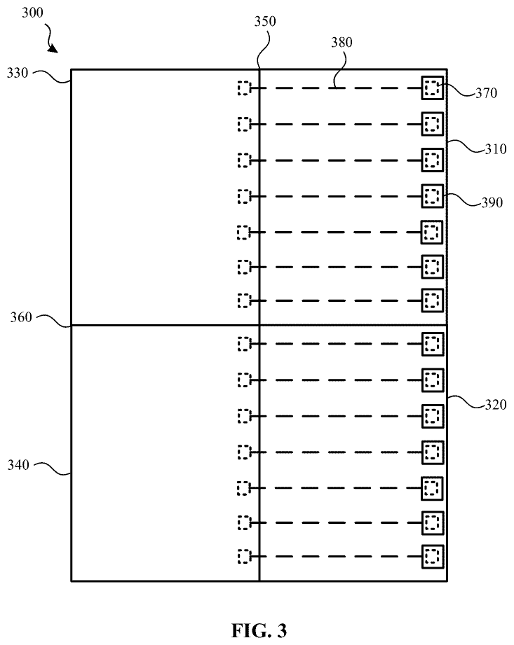

FIG. 3 illustrates a semiconductor die matrix tile 300 having a number of unsingulated semiconductor dies according to yet another example. In this example, the semiconductor die matrix tile 300 includes a first semiconductor die 310, a second semiconductor die 320, a third semiconductor die 330 and a fourth semiconductor die 340. Each semiconductor die is unsingulated from the other.

As such a first die separation line 350 is uncut and/or is visible and extends between the first semiconductor die 310 and the third semiconductor die 330 and also extends between the second semiconductor die 320 and the fourth semiconductor die 340. Additionally, a second die separation line 360 is uncut and/or is visible between the third semiconductor die 330 and the fourth semiconductor die 340 and between the first semiconductor die 310 and the second semiconductor die 320.

As with other examples described herein, a RDL is provided on or over a surface of each semiconductor die. Additionally, each semiconductor die includes one or more bond pads 370 proximate an edge. However, in some examples and due to the positioning of the third semiconductor die 330 with respect to the first semiconductor die 310 and due to the positioning of the fourth semiconductor die 340 with respect to the second semiconductor die 320, bond pads 370 on the third semiconductor die 330 and the fourth semiconductor die 340 are not easily accessible (e.g., are not easily accessible by bond wires).

As such, one or more traces 380 or other communication paths within the RDL electrically couple the third semiconductor die 330 to the first semiconductor die 310 and electrically couple the fourth semiconductor die 340 to the second semiconductor die 320. As with previous examples, the bond pads 370 and/or the traces 380 are also used to communicatively couple one or more of the semiconductor dies to a RDL bond pad 390 provided on or adjacent the RDL layer. The RDL bond pad 390 provides a connection point for a bond wire.

In other examples, the traces 380 electrically couple one of the semiconductor dies to two or more of the other semiconductor dies. For example, the traces 380 electrically couple the third semiconductor die 330 to the second semiconductor die 320 and/or to the fourth semiconductor die 340. Additionally, the traces 380 can couple any number of bond pads on each semiconductor die to various other bond pads on each semiconductor die.

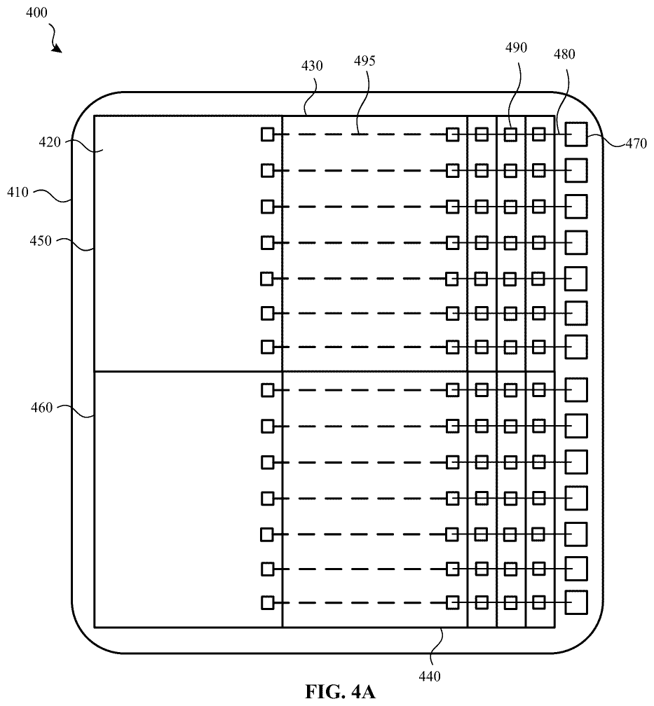

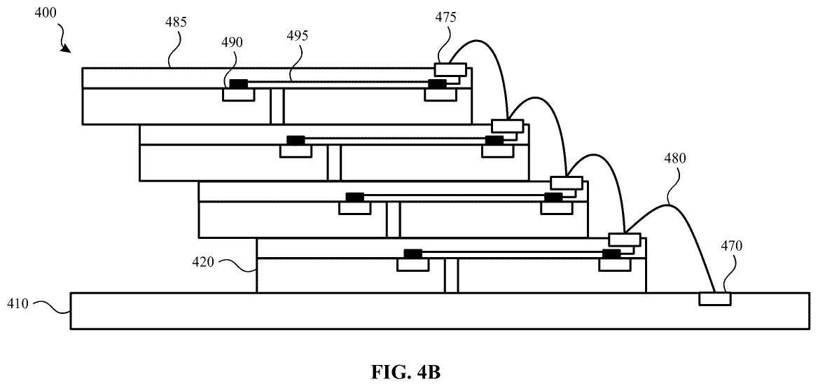

FIG. 4A illustrates a semiconductor package 400 having a stack of semiconductor die matrix tiles 420 according to an example. In an example, each semiconductor die matrix tile in the stack of semiconductor die matrix tiles 420 is similar to the semiconductor die matrix tile 300 shown and described with respect to FIG. 3. For example, each semiconductor die matrix tile in the stack of semiconductor die matrix tiles 420 includes a first semiconductor die 430, a second semiconductor die 440, a third semiconductor die 450 and a fourth semiconductor die 460.

Each semiconductor die is unsingulated or conjoined with each other in the manner as previously described. For example, because the semiconductor dies are unsingulated, one or more die separation lines between the various semiconductor dies remain visible and/or are uncut.

In an example, the stack of semiconductor die matrix tiles 420 is provided on a substrate 410. Additionally, each semiconductor die matrix tile in the stack of semiconductor die matrix tiles 420 is electrically coupled to the substrate 410. For example bond wires 480 are used to electrically couple a bond pad 470 on a surface of the substrate 410 to corresponding RDL bond pads 475 associated with an RDL layer on each semiconductor die in each semiconductor die matrix tile of the stack of semiconductor die matrix tiles 420.

Additionally, one or more traces 495 or other communication paths/circuitry are used to electrically and/or communicatively couple bond pads 490 of two of more of the semiconductor dies to each other. For example, one or more traces 495 extend between various bond pads 490 of the first semiconductor die 430 and the third semiconductor die 450 and the various bond pads 490 of the second semiconductor die 440 and the fourth semiconductor die 460.

FIG. 4B illustrates a cross-section view of the semiconductor package 400 of FIG. 4A according to an example. As shown in FIG. 4B, a redistribution layer (RDL) 485 is provided over/on a surface of the each semiconductor die matrix tile 420. In an example, the traces 495 that connect the bond pads 490 on the various semiconductor dies are contained within the RDL 485. Additionally, the RDL 485 includes a bond pad 475 or other connection point that enables the semiconductor die matrix tile 420 to be communicatively coupled to the bond pad 470 on the substrate 410 and/or another semiconductor die matrix tile 420.

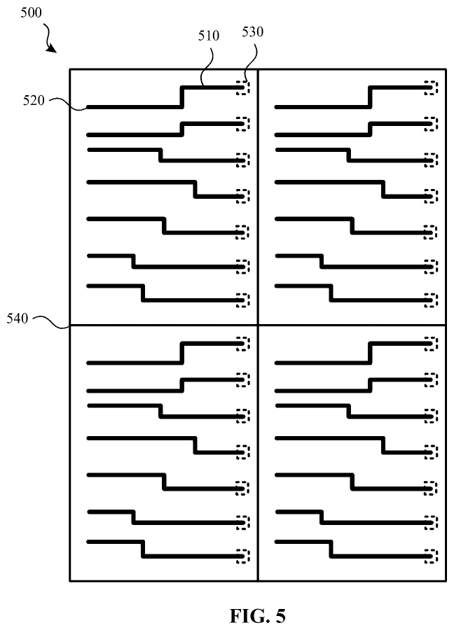

FIG. 5 illustrates a RDL 500 for a semiconductor die matrix tile according to an example. In an example, the RDL 500 is included in any of the semiconductor die matrix tiles shown and described herein. The RDL 500 is fabricated in manner so as to cover all or substantially all of a surface of the semiconductor die matrix tiles shown and described herein. For example, the RDL 500 includes or otherwise covers one or more die separation lines 540 on or otherwise associated with the semiconductor die matrix tile.

In an example, the RDL 500 is, or includes, one or more traces 510 that redistribute electrical connections from a first location 520 to a second location 530 (or vice versa). For example, the RDL 500 is used to route signals from bond pads on each semiconductor die in each semiconductor die matrix tile to other bond pads on other semiconductor die matrix tiles. In an example, the RDL 500 also includes one or more RDL bond pads such as previously described. In an example, the RDL bond pads are communicatively coupled to one or more solder balls that enable a semiconductor package to be utilized as a flip chip package when the semiconductor package is mounted to a printed circuit board PCB.

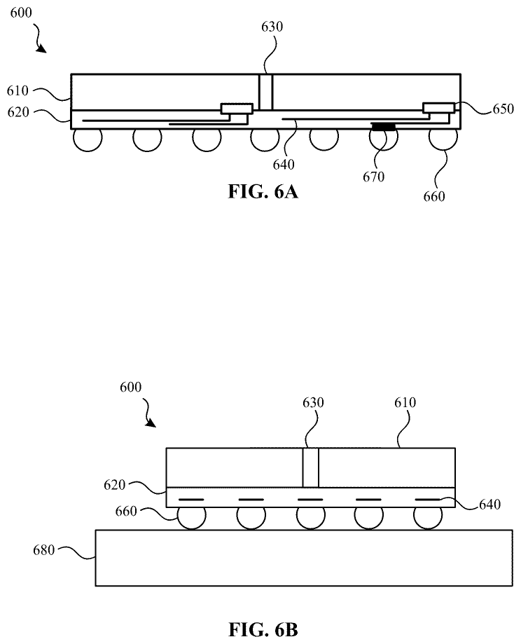

FIG. 6A illustrates a flip chip semiconductor package 600 having a semiconductor die matrix tile 610 according to an example. In an example, the semiconductor die matrix tile 610 is similar to the various semiconductor die matrix tiles shown and described with respect to FIG. 1A and FIG. 1B and/or FIG. 3. Although a single semiconductor die matrix tile 610 is shown, the flip chip semiconductor package 600 may include a stack of semiconductor die matrix tiles 610.

As with other examples previously described, the semiconductor die matrix tile 610 includes a RDL 620. In an example, the RDL 620 is similar to the RDL 500 shown and described with respect to FIG. 5. The RDL 620 is provided on a surface of the semiconductor die matrix tile 610 and extends across each semiconductor die and the die separation line 630 of the semiconductor die matrix tile 610.

In an example, the RDL 620 includes various traces 640 that connect bond pads 650 on at least one semiconductor die to each other and/or to one or more solder balls 660 or other interconnects. For example, a trace 640 in the RDL 620 is electrically coupled to one or more solder balls 660 using an under bump metallization 670.

FIG. 6B illustrates the semiconductor package 600 of FIG. 6A being electrically coupled to a printed circuit board (PCB) 680 according to an example. In the example, shown, the semiconductor package 600 includes a semiconductor die matrix tile 610 (or multiple stacks of semiconductor die matrix tiles) that includes multiple unsingulated dies and a die separation line 630. Each semiconductor die matrix tile 610 of the semiconductor package 600 is electrically coupled to one or more solder balls 660 using various traces 640 or other communication paths provided in the RDL 620.

In an example, the semiconductor package 600 is a NAND memory package. Because the semiconductor package 600 includes semiconductor die matrix tiles (and in some examples multiple stacks of semiconductor die matrix tiles), the NAND memory package has at least twice the capacity of currently available NAND memory packages that do not use the semiconductor die matrix tiles described herein.

Additionally, use of semiconductor die matrix tiles in the semiconductor package 600 enables reduced spacing between die stacks when compared with current solutions because at least two semiconductor dies are conjoined or unsingulated. As such, higher density can be achieved (when compared with current solutions) within the same or smaller package, which leads to higher total memory capacity within the same (or smaller) form factor.

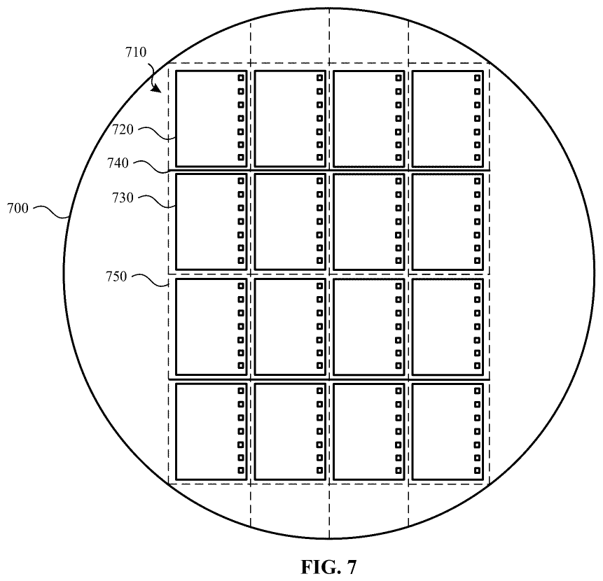

FIG. 7 illustrates a semiconductor wafer 700 having a number of semiconductor dies forming a semiconductor die matrix tile 710 according to an example. In the example shown, the wafer 700 has yet to undergo a singulation process in which some semiconductor dies will be singulated from other semiconductor dies while other semiconductor dies will remain unsingulated.

For example, during the singulation process, the wafer 700 will be singulated in a manner such that 2×1 semiconductor die matrix tiles 710 will be formed. As such, the wafer 700 will be singulated along a first set of scribe lanes or die separation lines 750 (represented by the dashed lines). However, a second set of scribe lanes or die separation lines 740 (represented by the solid lines) will be skipped in order to form the 2×1 semiconductor die matrix tile 710 which includes a first semiconductor die 720 and a second semiconductor die 730.

Although FIG. 7 illustrates a 2×1 semiconductor die matrix tile 710, it is contemplated that a wafer 700 may be singulated in any desired pattern to form any size or configuration of semiconductor die matrix tiles.

Accordingly, examples of the present disclosure describe a semiconductor package, comprising: a substrate; and a stack of semiconductor die matrix tiles electrically coupled to the substrate, wherein each semiconductor die matrix tile in the stack of semiconductor die matrix tiles comprises: a first semiconductor die; a second semiconductor die unsingulated from the first semiconductor die such that the first semiconductor die and the second semiconductor die form a single unit; and a redistribution layer, the redistribution layer including one or more communication paths that electrically couple the first semiconductor die to the second semiconductor die. In an example, the semiconductor package also includes a first plurality of bond pads on the first semiconductor die and a second plurality of bond pads on the second semiconductor die. In an example, the semiconductor package also includes a redistribution layer bond pad, the redistribution layer bond pad being electrically coupled to one or more bond pads on at least one of the first semiconductor die and the second semiconductor die. In an example, the semiconductor package also includes a plurality of solder balls provided on a bottom surface of the substrate. In an example, the redistribution layer bond pad is electrically coupled to at least one solder ball of the plurality of solder balls. In an example, each semiconductor die matrix tile further comprises: a third semiconductor die; and a fourth semiconductor die, wherein the third semiconductor die and the fourth semiconductor die are unsingulated from the first semiconductor die and the second semiconductor die such that the first semiconductor die, the second semiconductor die, the third semiconductor die and the fourth semiconductor die form a single unit. In an example, the semiconductor package also includes at least one trace electrically coupling the first semiconductor die and the third semiconductor die. In an example, a die separation line is visible on at least one semiconductor die matrix tile.

Examples also describe a semiconductor package, comprising: a substrate; a first semiconductor die matrix tile comprising a first plurality of conjoined semiconductor dies; a second semiconductor die matrix tile stacked on top of the first semiconductor die matrix tile and comprising a second plurality of conjoined memory dies; a first plurality of redistribution layer bond pads provided on the first semiconductor die matrix tile; a second plurality of redistribution layer bond pads provided on the second semiconductor die matrix tile; and a bond wire extending between at least a first redistribution layer bond pad of the first plurality of redistribution layer bond pads on the first semiconductor die matrix tile and at least a first redistribution layer bond pad of the second plurality of redistribution layer bond pads on the second semiconductor die matrix tile. In an example, the semiconductor package also includes a redistribution layer provided on a surface of the first semiconductor die matrix tile. In an example, the semiconductor package also includes a plurality of traces provided within the redistribution layer and electrically coupling the first plurality of conjoined semiconductor dies. In an example, the redistribution layer bond pad is electrically coupled to one or more interconnects associated with the semiconductor package. In an example, a die separation line is visible on at least one of the first semiconductor die matrix tile and the second semiconductor die matrix tile. In an example, the die separation line was skipped during a die singulation process.

Other examples describe a semiconductor package, comprising: a substrate; a stack of semiconductor die matrix tiles, wherein each semiconductor die matrix tile in the stack of semiconductor die matrix tiles comprises: a first semiconductor die; and a second semiconductor die unsingulated from the first semiconductor die such that the first semiconductor die and the second semiconductor die form a single unit; a trace distribution means provided on the first semiconductor die and the second semiconductor die; and a trace means provided within the trace distribution means, the trace means electrically coupling the second semiconductor die to the first semiconductor die; and a connection means for electrically coupling each semiconductor die matrix tile in the stack of semiconductor die matrix tiles to the substrate. In an example, the connection means for electrically coupling each semiconductor die matrix tile in the stack of semiconductor die matrix tiles are bond pads associated with the trace distribution means. In an example, the semiconductor package also includes interconnection means associated with the connection means. In an example, the interconnection means are solder balls. In an example, the semiconductor package also includes circuitry means for electrically coupling each semiconductor die matrix tile in the stack of semiconductor die matrix tiles to the substrate. In an example, the semiconductor package also includes a delineation means provided between the first semiconductor die and the second semiconductor die.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an embodiment with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to embodiments of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute via the processor or other programmable data processing apparatus, create means for implementing the functions and/or acts specified in the schematic flowchart diagrams and/or schematic block diagrams block or blocks. Additionally, it is contemplated that the flowcharts and/or aspects of the flowcharts may be combined and/or performed in any order.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C, A-B, A-C, B-C, and A-B-C, as well as multiples of the same members. Likewise, “at least one of: A, B, and C” is intended to cover A, B, C, A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A semiconductor package, comprising:
a substrate; and
a stack of semiconductor die matrix tiles electrically coupled to the substrate, wherein each semiconductor die matrix tile in the stack of semiconductor die matrix tiles comprises:
a first semiconductor die;
a second semiconductor die unsingulated from the first semiconductor die such that the first semiconductor die and the second semiconductor die form a single unit; and
a redistribution layer, the redistribution layer including one or more communication paths that electrically couple the first semiconductor die to the second semiconductor die.

2. The semiconductor package of claim 1, further comprising a first plurality of bond pads on the first semiconductor die and a second plurality of bond pads on the second semiconductor die.

3. The semiconductor package of claim 2, further comprising a redistribution layer bond pad, the redistribution layer bond pad being electrically coupled to one or more bond pads on at least one of the first semiconductor die and the second semiconductor die.

4. The semiconductor package of claim 3, further comprising a plurality of solder balls provided on a bottom surface of the substrate.

5. The semiconductor package of claim 4, wherein the redistribution layer bond pad is electrically coupled to at least one solder ball of the plurality of solder balls.

6. The semiconductor package of claim 1, wherein each semiconductor die matrix tile further comprises:
a third semiconductor die; and
a fourth semiconductor die, wherein the third semiconductor die and the fourth semiconductor die are unsingulated from the first semiconductor die and the second semiconductor die such that the first semiconductor die, the second semiconductor die, the third semiconductor die and the fourth semiconductor die form a single unit.

7. The semiconductor package of claim 6, further comprising at least one trace electrically coupling the first semiconductor die and the third semiconductor die.

8. The semiconductor package of claim 1, wherein a die separation line is visible on at least one semiconductor die matrix tile.

9. A semiconductor package, comprising:
a substrate;
a first semiconductor die matrix tile comprising a first plurality of conjoined semiconductor dies;
a second semiconductor die matrix tile stacked on top of the first semiconductor die matrix tile and comprising a second plurality of conjoined memory dies;
a first plurality of redistribution layer bond pads provided on the first semiconductor die matrix tile;
a second plurality of redistribution layer bond pads provided on the second semiconductor die matrix tile; and
a bond wire extending between at least a first redistribution layer bond pad of the first plurality of redistribution layer bond pads on the first semiconductor die matrix tile and at least a first redistribution layer bond pad of the second plurality of redistribution layer bond pads on the second semiconductor die matrix tile.

10. The semiconductor package of claim 9, further comprising a redistribution layer provided on a surface of the first semiconductor die matrix tile.

11. The semiconductor package of claim 10, further comprising a plurality of traces provided within the redistribution layer and electrically coupling the first plurality of conjoined semiconductor dies.

12. The semiconductor package of claim 9, wherein the redistribution layer bond pad is electrically coupled to one or more interconnects associated with the semiconductor package.

13. The semiconductor package of claim 9, wherein a die separation line is visible on at least one of the first semiconductor die matrix tile and the second semiconductor die matrix tile.

14. The semiconductor package of claim 13, wherein the die separation line was skipped during a die singulation process.

15. A semiconductor package, comprising:
a substrate;
a stack of semiconductor die matrix tiles, wherein each semiconductor die matrix tile in the stack of semiconductor die matrix tiles comprises:
a first semiconductor die; and
a second semiconductor die unsingulated from the first semiconductor die such that the first semiconductor die and the second semiconductor die form a single unit;
a trace distribution means provided on the first semiconductor die and the second semiconductor die; and
a trace means provided within the trace distribution means, the trace means electrically coupling the second semiconductor die to the first semiconductor die; and
a connection means for electrically coupling each semiconductor die matrix tile in the stack of semiconductor die matrix tiles to the substrate.

16. The semiconductor package of claim 15, wherein the connection means for electrically coupling each semiconductor die matrix tile in the stack of semiconductor die matrix tiles are bond pads associated with the trace distribution means.

17. The semiconductor package of claim 15, further comprising interconnection means associated with the connection means.

18. The semiconductor package of claim 17, wherein the interconnection means are solder balls.

19. The semiconductor package of claim 15, further comprising circuitry means for electrically coupling each semiconductor die matrix tile in the stack of semiconductor die matrix tiles to the substrate.

20. The semiconductor package of claim 15, further comprising a delineation means provided between the first semiconductor die and the second semiconductor die.
